(19) United States
(12) Patent Application Publication
(10) Pub. No.: US 2026/0064006 A1
(43) Pub. Date: Mar. 5, 2026

(54) EXTREME ULTRA-VIOLET LITHOGRAPHY SYSTEM HAVING SENSOR MODULE

(71) Applicant: Samsung Electronics Co., Ltd., Suwon-si (KR)

(72) Inventors: Ik Sun PARK, Suwon-si (KR); Akinori OKUBO, Suwon-si (KR); Eun Hee JEANG, Suwon-si (KR); Kyoung Whan OH, Suwon-si (KR)

(21) Appl. No.: 19/222,895

(22) Filed: May 29, 2025

(30) Foreign Application Priority Data
Aug. 28, 2024 (KR) 10-2024-0116063

(51) Int. Cl. G03F 7/00

(52) U.S. Cl. CPC G03F 7/70091; G03F 7/70033; G03F 7/70075

(57) ABSTRACT

An extreme ultra-violet (EUV) lithography system includes a source module generating light, a field facet mirror including first mirrors that collect the light transmitted from the source module, a pupil facet mirror including second mirrors that transmit the light transmitted from the field facet mirror to a reticle, a projection optical system transmitting the light reflected from the reticle to a substrate, a sensor module disposed on a substrate stage that supports the substrate and generating a first image representing a light intensity distribution, and a processor performing a Fourier transformation on the first image to generate a second image representing a first pupil region defined by a first center point and a plurality of second center points each spaced apart from the first center point by a first distance. The first center point is located at a center of the first pupil region.

### CROSS-REFERENCE TO RELATED APPLICATION

This application claims priority from Korean Patent Application No. 10-2024-0116063 filed on Aug. 28, 2024 in the Korean Intellectual Property Office, and all the benefits accruing therefrom under 35 U.S.C. 119, the contents of which in its entirety are herein incorporated by reference.

### BACKGROUND

### 1. Field of the Invention

The present invention relates to a monitoring device. More specifically, the present invention relates to a monitoring device that is applicable to exposure equipment using extreme ultra-violet light.

### 2. Description of the Related Art

As a semiconductor circuit line width becomes increasingly finer, light sources of shorter wavelengths are required. For example, extreme ultra-violet (EUV) light is used as an exposure source.

Illumination optics for transmitting the EUV light to an EUV mask, and projection optics for projecting the EUV light reflected from the EUV mask onto an exposure target may include a plurality of mirrors. As the difficulty of the exposure process gradually increases, small errors that occur in the mirrors may cause serious errors in pattern formation on a wafer.

### SUMMARY

Aspects of the present invention provide a monitoring device that may more precisely monitor the EUV light mapped onto the mirrors.

However, aspects of the present invention are not restricted to the one set forth herein. The above and other aspects of the present invention will become more apparent to one of ordinary skill in the art to which the present invention pertains by referencing the detailed description of the present invention given below.

According to an aspect of the present disclosure, an extreme ultra-violet (EUV) lithography system includes a source module which generates light, a field facet mirror which includes a plurality of first mirrors that collect the light transmitted from the source module, a pupil facet mirror which includes a plurality of second mirrors that transmit the light transmitted from the field facet mirror to a reticle, a projection optical system which transmits the light reflected from the reticle to a substrate, a sensor module which is disposed on a substrate stage that supports the substrate, and which generates a first image representing a light intensity distribution, and a processor performing a Fourier transformation on the first image to generate a second image representing a first pupil region defined by a first center point and a plurality of second center points each spaced apart from the first center point by a first distance. The first center point is located at a center of the first pupil region.

According to an aspect of the present disclosure, an extreme ultra-violet (EUV) lithography system includes a source module which generates an extreme ultra-violet light, a first optical system which includes a field facet mirror that collects the extreme ultra-violet light and a pupil facet mirror that transmits the extreme ultra-violet light transmitted from the field facet mirror to a reticle, the field facet mirror including a plurality of first mirrors, and the pupil facet mirror including a plurality of second mirrors, a second optical system which transmits the extreme ultra-violet light reflected from the reticle to a substrate, a sensor module which is disposed on a substrate stage that supports the substrate, and which generates a first image representing an intensity distribution of the extreme ultra-violet light, and a processor performing a Fourier transform on the first image to generate a second image representing a first pupil region having a first center point and a plurality of second center points and measuring an intensity of the extreme ultra-violet light mapped to each of the plurality of second mirrors from the first center point. The plurality of second center points are associated with the plurality of second mirrors.

According to an aspect of the present disclosure, an extreme ultra-violet (EUV) lithography system includes a source module which generates an extreme ultra-violet light, an optical module which transfers a pattern onto a substrate, using the extreme ultra-violet light, the optical module including a collector which collects and reflects the extreme ultra-violet light generated from the source module, an illumination optical system which includes a field facet mirror including a plurality of first mirrors that reflects the extreme ultra-violet light emitted from the collector, and a pupil facet mirror including a plurality of second mirrors that transmit the extreme ultra-violet light transmitted from the field facet mirror to a reticle, and a projection optical system which transmits the extreme ultra-violet light reflected from the reticle to the substrate, a sensor module which is disposed on a substrate stage that supports the substrate, and which generates a first image on an intensity distribution of the extreme ultra-violet light, and a processor performing a Fourier transformation on the first image to generate a second image representing a first pupil region defined by a first center point and a plurality of second center points. The plurality of second center points are associated with centers of the plurality of second mirrors. The first center point corresponds to a center of the first pupil region. The processor further measures an intensity of the extreme ultra-violet light mapped to the plurality of second mirrors, using the first center point.

Specific matters of other embodiments are included in the detailed description and drawings.

### BRIEF DESCRIPTION OF THE DRAWINGS

The above and other aspects and features of the present invention will become more apparent by describing in detail exemplary embodiments thereof referring to the attached drawings, in which:

FIG. 1 is a schematic diagram for explaining a monitoring device according to some embodiments;

FIG. 2 is a diagram for explaining a first image measured by a sensor module according to some embodiments;

FIG. 3 is a diagram for explaining a second image generated from the first image of FIG. 2;

FIG. 4 is an enlarged view of a partial region of the first image of FIG. 2;

FIG. 5 is a diagram for explaining a pupil region acquired from the second image of FIG. 3;

FIGS. 6 and 7 are diagrams for explaining tracking of the intensity of extreme ultra-violet mapped to each mirror of a pupil facet mirror;

FIG. 8 is a diagram for explaining obtaining of a pupil region in which the intensity of extreme ultra-violet is maximized;

FIG. 9 is a diagram for explaining obtaining of an optimized pupil region, using a linear interpolation algorithm;

FIG. 10 is a diagram for explaining obtaining of an optimized pupil region, using a Gaussian function fitting algorithm; and

FIG. 11 is a flowchart for explaining a monitoring method, using a monitoring device according to some embodiments.

### DETAILED DESCRIPTION OF THE EMBODIMENTS

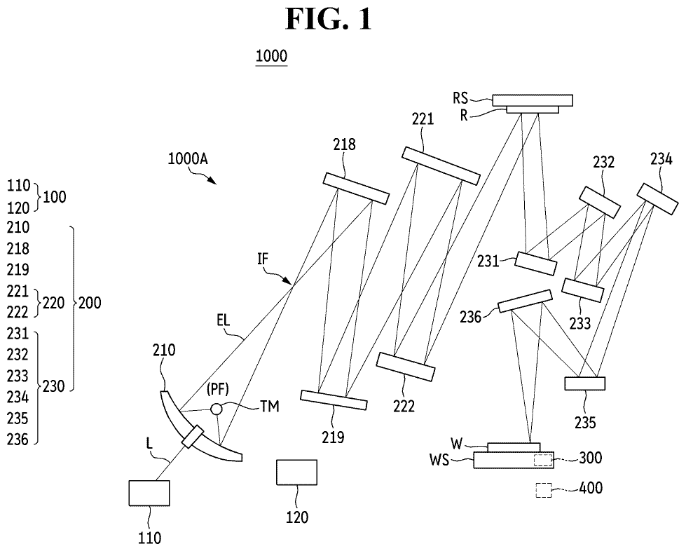

A monitoring device according to some embodiments and a monitoring method using the same will be described below referring to FIGS. 1 to 11.

FIG. 1 is a schematic diagram for explaining a monitoring device according to some embodiments.

Referring to FIG. 1, a monitoring device 1000 (i.e., an extreme ultra-violet lithography system) according to some embodiments may include an extreme ultra-violet exposure device 1000A, a sensor module 300, and a processor 400. The extreme ultra-violet exposure device 1000A may include a source module 100, an optical module 200, a reticle stage RS, and a substrate stage WS. In some embodiments, the monitoring device 1000 for manufacturing the semiconductor device may be a device for manufacturing the semiconductor device.

The source module 100 may generate extreme ultra-violet EL (i.e., an extreme ultra-violet light) from a laser L. The source module 100 may include a laser generator 110 and a droplet generator 120.

Although it is not specifically shown, a chamber may provide a space in which plasma is generated to generate the extreme ultra-violet EL to be described below. In some embodiments, the inside of the chamber may be provided in a vacuum (e.g., about 1 Torr or less). The inside of the chamber provided in a vacuum may facilitate the progression of the laser L and/or the extreme ultra-violet EL.

The laser generator 110 may generate the laser L and irradiate it into the chamber. The laser L generated from the laser generator 110 may be irradiated toward a second focus IF of a collector 210 to be described below. The collector 210 may be a prolate ellipsoid having a concavely convergent shape. The laser L may be, for example, but not limited to, a CO₂ laser beam or an NdYAG (Neodymium-doped Yttrium Aluminum Garnet) laser beam.

The droplet generator 120 may supply source droplets TM as a target material for generating the extreme ultra-violet EL. For example, the droplet generator 120 may supply source droplets TM into the chamber, using a droplet supply nozzle installed in the chamber. The droplet supply nozzle may provide the source droplets TM into the chamber at a certain period. The source droplets TM provided inside the chamber may be irradiated by the laser L generated from the laser generator 110 to generate plasma.

The source droplets TM are irradiated by a laser L, and may include at least one extreme ultra-violet emitting element, for example, tin (Sn), xenon (Xe), lithium (Li), or titanium (Ti), having an emission line of wavelengths in the extreme ultra-violet range. The extreme ultra-violet emitting element may exist in the form of droplets and/or solid particles included in the droplets.

In some embodiments, the source droplets TM may include tin (Sn). For example, the source droplets TM may include pure tin, tin compounds, tin alloys, or a combination thereof. The tin compounds may include, but not limited to, for example, at least one of SnBr₄, SnBr₂, and SnH. The tin alloys may include, but not limited to, for example, at least one of Sn—Ga, Sn—In, and Sn—In—Ga.

The optical module 200 may include optical elements that transfer a pattern onto the substrate W, using the extreme ultra-violet EL. The optical module 200 may include a collector 210, delay mirrors 218 and 219, an illumination optical system 220, and a projection optical system 230.

The collector 210 may be disposed inside the chamber. The collector 210 may have a first focal point PF and a second focal point IF. For example, the collector 210 may include a curved surface having a prolate ellipsoid shape with the first focal point PF and the second focal point IF farther than the first focal point PF.

The collector 210 may collect and reflect the extreme ultra-violet EL generated from the source module 100. The collector 210 may selectively collect and reflect the extreme ultra-violet EL having a wavelength in the extreme ultra-violet range among various wavelengths of light emitted from the plasma generated from the source droplets TM. The extreme ultra-violet EL may have a wavelength of about 1 nm to about 31 nm. For example, the extreme ultra-violet EL may have a wavelength of about 10 nm to about 14 nm.

The extreme ultra-violet EL generated at the first focal point PF may be reflected toward the second focal point IF by the collector 210. That is, the extreme ultra-violet EL may be concentrated at the second focal point IF by the collector 210 and discharged.

In some embodiments, the collector 210 may include a multi-layer mirror that provides an elliptical reflecting surface. The multi-layer mirror may include, but not limited to, a structure in which a plurality of films selected from the group consisting of molybdenum (Mo), silicon (Si), silicon carbide (SiC), boron carbide (B₄C), molybdenum carbide (Mo₂C), and silicon nitride (Si₃N₄) are alternately stacked one by one.

The delay mirrors 218 and 219 may be disposed between the source module 100 and the illumination optical system 220. The delay mirrors 218 and 219 may transmit the extreme ultra-violet EL generated from the source module 100 to a field facet mirror 221, which will be described below.

The extreme ultra-violet EL generated from the extreme ultra-violet exposure device 1000A may be irradiated to the illumination optical system 220.

The illumination optical system 220 may include a field facet mirror (FFM) 221 and a pupil facet mirror (PFM) 222.

The field facet mirror 221 may collect the reflected extreme ultra-violet. Although it is not specifically shown, the field facet mirror 221 may include a plurality of first mirrors. For example, the field facet mirror 221 may include, but not limited to, approximately hundreds of first mirrors.

The pupil facet mirror 222 may transmit the extreme ultra-violet transmitted from the field facet mirror 221 to the reticle R. Although it is not specifically shown, the pupil facet mirror 222 may include a plurality of second mirrors. For example, the pupil facet mirror 222 may include, but not limited to, approximately hundreds to thousands of second mirrors. The pupil facet mirror 222 may include multiple reflective surfaces (i.e., mirror surfaces) called “pupil facets” designed to precisely control the distribution of light within the pupil plane of the optical system, allowing for uniform illumination across a target area.

The illumination optical system 220 may adjust the intensity distribution of the extreme ultra-violet EL. The illumination optical system 220 may be made up of a concave mirror, a convex mirror or a combination thereof so that the paths of the extreme ultra-violet EL may be diversified.

Although the illumination optical system 220 is only shown to include two concave mirrors in FIG. 1, this is merely an example. The placement and number of mirrors included in the illumination optical system 220 may be various. The illumination optical system 220 may include an independent vacuum chamber, and may further include various lenses and optical elements that are not shown in FIG. 1.

The reticle R may be mounted on the reticle stage RS. The reticle stage RS may move the reticle R in a horizontal direction to control the position of the reticle R. For example, the reticle stage RS may move in the horizontal direction with the reticle R mounted thereon using an electrostatic chuck. The reticle R may be attached to a bottom side of the reticle stage RS so that a side with the optical patterns formed thereon is directed downward.

Although it is not specifically shown, a slit through which the extreme ultra-violet EL passes may be disposed below the reticle stage RS. The slit may shape the shape of the extreme ultra-violet EL transmitted from the illumination optical system 220 to the reticle R attached onto the reticle stage RS. The extreme ultra-violet EL transmitted from the illumination optical system 220 passes through the slit, and may be irradiated onto the surface of the reticle R.

The extreme ultra-violet EL reflected from the reticle R mounted on the reticle stage RS passes through the slit, and may be transmitted to the projection optical system 230. The projection optical system 230 may receive the extreme ultra-violet EL that has passed through the slit, and transmit it to the substrate W. The projection optical system 230 may include a plurality of optical elements 231 to 236. The plurality of optical elements 231 to 236 may correct various aberrations.

Although FIG. 1 only shows that the plurality of optical elements 231 to 236 include six concave mirrors, this is merely an example. The placement and number of mirrors included in the plurality of optical elements 231 to 236 may be various.

The substrate W may be mounted on the substrate stage WS. The substrate stage WS may move the substrate W in the horizontal direction to control the position of the substrate W. For example, the substrate stage WS may move in the horizontal direction with the substrate W mounted thereon, using an electrostatic chuck. Accordingly, the projection optical system 230 may reduce and project the patterns formed on the reticle R onto the substrate W.

The substrate W may be used to manufacture semiconductor devices. The semiconductor devices may include, for example, semiconductor elements such as silicon (Si) and germanium (Ge), or compound semiconductors such as SiC (silicon carbide), GaAs (gallium arsenide), InAs (indium arsenide), and InP (indium phosphide). In some embodiments, the semiconductor devices may include a conductive region, for example, an impurity-doped well or an impurity-doped structure. The semiconductor devices may include various element isolation structures, such as shallow trench isolation (STI). In some embodiments, the semiconductor devices may have a silicon-on-insulator (SOI) structure. For example, the semiconductor devices may include a buried oxide layer (BOX).

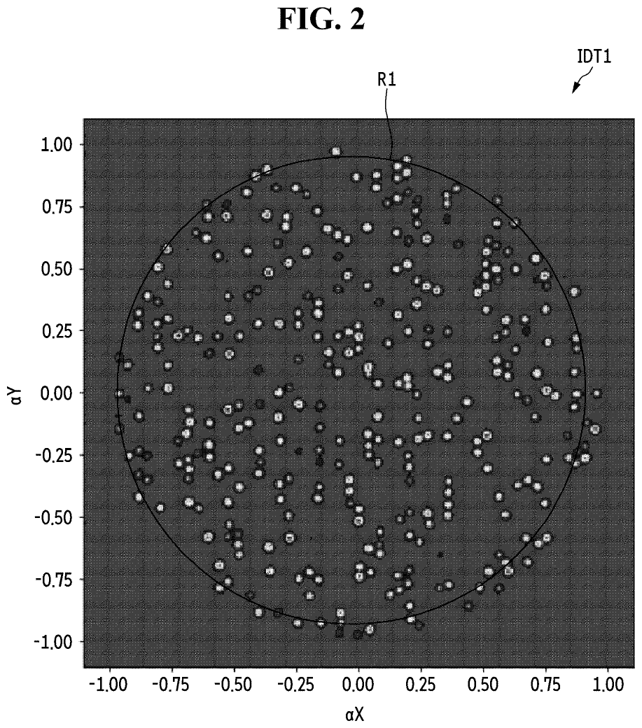

The sensor module 300 may be disposed on the substrate stage WS that supports the substrate W. As it will be described below, the sensor module 300 may receive the extreme ultra-violet EL and generate a first image (IDT1 of FIG. 2) on the intensity distribution of the extreme ultra-violet EL. In an embodiment, the first image IDT1 may represent the intensity distribution of the extreme ultra-violet EL reflected from the reticle R. In an embodiment, the sensor module 300 may include a back-illuminated charge-coupled device (CCD) or a complementary-metal-oxide-semiconductor (CMOS) sensor which is coated with materials that enhance sensitivity to EUV wavelengths. In an embodiment, the sensor module 300 may include a microchannel plates (MCPs) or other photo-counting detectors for measuring a light intensity distribution of EUV light.

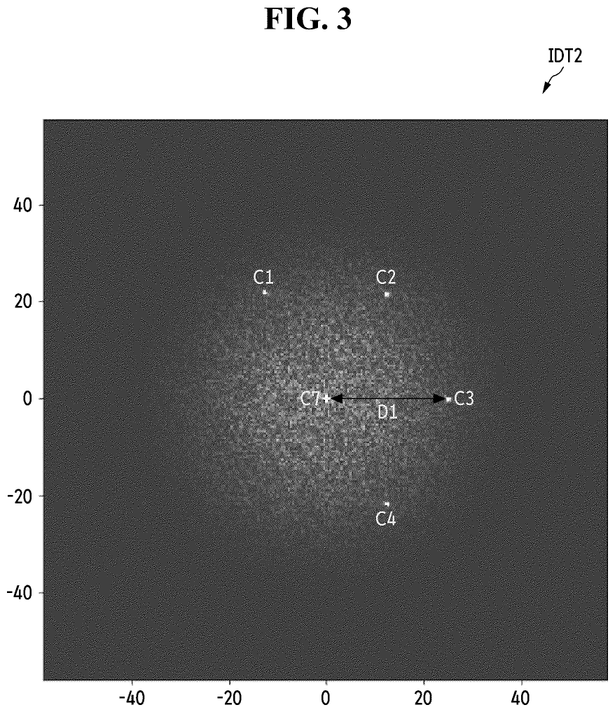

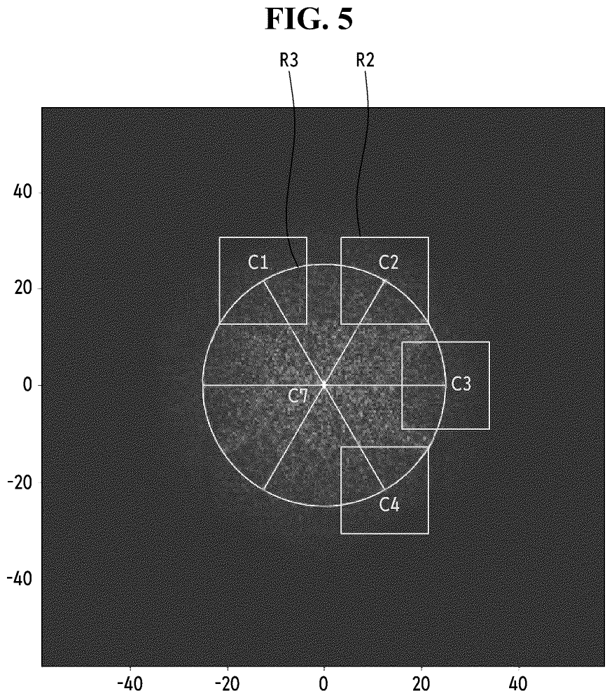

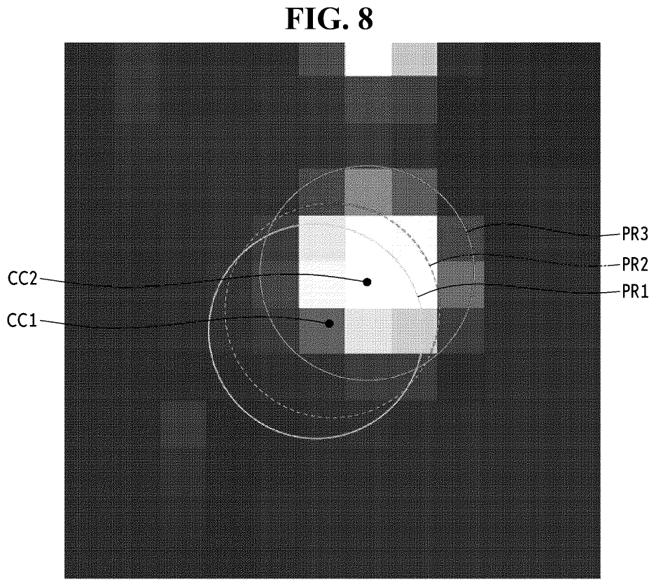

The processor 400 may receive the first image (IDT1 of FIG. 2) from the sensor module 300 to generate a second image (IDT2 of FIG. 3) obtained by converting the first image (IDT1 of FIG. 2). The processor 400 may generate coordinates about a center point of the third pupil region (PR3 of FIG. 8) on the basis of the center point of the third region (R3 of FIG. 5) of the second image (IDT2 of FIG. 3).

Accordingly, the processor 400 may more precisely measure the intensity and position of the extreme ultra-violet EL mapped to each of the plurality of second mirrors, and alignment with the mirrors. The processor 400 may calculate the intensity loss of the extreme ultra-violet EL at each of the plurality of second mirrors.

The processor 400 may monitor in real time the intensity and position of the extreme ultra-violet EL transmitted from the field facet mirror 221 to the pupil facet mirror 222, and alignment with the mirrors.

Accordingly, it is possible to grasp whether the region in which the intensity loss of the extreme ultra-violet EL occurs is the illumination optical system 220 or the projection optical system 230 when the pattern image is affected in the exposure process.

The processor 400 may be implemented as hardware, firmware, software or any combination thereof. For example, the processor 400 may be a computing device such as a workstation computer, a desktop computer, a laptop computer, and a tablet computer. Furthermore, the processor 400 may include a storage unit in which a program for executing various algorithms used to acquire the coordinates of the pupil region is stored. The program may be stored in a storage medium that is readable by a computer.

For example, the processor 400 may include a memory device such as a ROM (Read Only Memory) and a RAM (Random Access Memory), and a processor configured to execute predetermined calculations and algorithms, for example, a microprocessor, a CPU (Central Processing Unit), or a GPU (Graphics Processing Unit). Furthermore, the processor 400 may include a receiver and a transmitter for receiving and transmitting electrical signals.

Specific operation of the processor 400 will be described below.

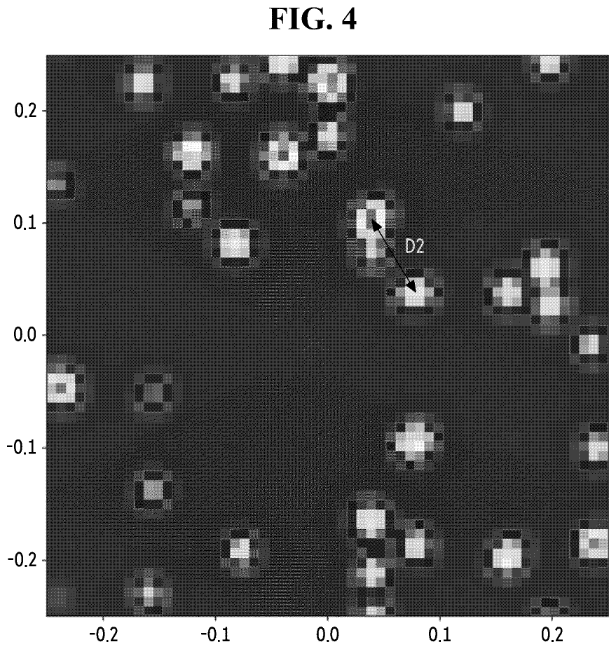

FIG. 2 is a diagram for explaining a first image measured by a sensor module according to some embodiments. FIG. 3 is a diagram for explaining a second image generated from the first image of FIG. 2. FIG. 4 is an enlarged view of a partial region of the first image of FIG. 2. FIG. 5 is a diagram for explaining a pupil region acquired from the second image of FIG. 3.

Referring to FIG. 2, the first image IDT1 may be an image obtained by measuring the intensity of extreme ultra-violet (EL of FIG. 1) corresponding to each of a plurality of second mirrors (not shown) of the pupil facet mirror (222 of FIG. 1). For example, the first image IDT1 may be an image obtained by measuring the intensity of extreme ultra-violet (EL of FIG. 1) reflected from each of a plurality of second mirrors of the pupil facet mirror 222 of FIG. 1. Each point of the first image IDT1 may represent the position of the extreme ultra-violet (EL of FIG. 1) and the intensity of the extreme ultra-violet (EL of FIG. 1) corresponding thereto. In an embodiment, each point of the first image IDT1 may be generated from the extreme ultra-violet EL reflected by a corresponding second mirror of the plurality of second mirrors of the pupil facet mirror 222 of FIG. 1. For example, when the number of the plurality of second mirrors of the pupil facet mirror 222 may be 1,620, the number of points in first image IDT1 may be the same of 1,620.

At the first image IDT1, a first region R1 which is a circle having a maximum diameter may be set on the basis of each point. For example, the perimeter of the first region R1 may correspond to an outer boundary of a region where the 1,620 points are located.

A horizontal axis of the first image IDT1 may refer to a ratio value αX about an X-direction diameter of the first region R1. A vertical axis of the first image IDT1 may refer to a ratio value αY about a Y-direction diameter of the first region R1. Although it is not specifically shown, the X-direction and the Y-direction may refer to directions perpendicular to each other on a plane. In an embodiment, the ratio values αX and αX are defined to describe the relative locations of the points in the first region R1.

Referring to FIG. 3, the processor 400 may perform a Fast Fourier Transform on the first image (IDT1 of FIG. 2) to generate a second image IDT2. In an embodiment, the second image IDT2 may be obtained by performing two-dimensional discrete Fourier transformation on the first image including information of an intensity distribution of a two-dimensional plane EUV light.

The second image IDT2 may have a first center point C7 and a plurality of second center points C1 to C4 each spaced apart from the first center point C7 by the same distance. Each of the horizontal axis and the vertical axis of the second image IDT2 may refer to Hertz (Hz). In an embodiment, when the two-dimensional discrete Fourie transformation is performed on the first image IDT1 obtained from the plurality of second mirrors arranged in the pupil facet mirror 222, the first center point C7 of a central peak and the plurality of center points C1 to C4 of pattern peaks are obtained in the second image IDT2. The first center point C7 may represent a low-frequency component of the first image IDT1 (i.e., the overall average intensity), and the plurality of center points C1 to C4 at specific locations away from the first center point C7 may correspond to the spatial frequency of the points of the first image IDT1.

At the second image IDT2, the first center point C7 and a plurality of second center points C1 to C4 may exist in a relatively bright portion, which may refer to a noise component of the image. The inventors have found that the hexagonal dots that appear in the second image IDT2 can be considered regular noise, and this regular noise represents the ideal honeycomb structure (i.e., a hexagon) of the pupil facet mirror 222 intended to be obtained. A first distance D1 between the first center point C7 and any one of the plurality of second center points C1 to C4 (e.g., C3) may be 25 Hz.

Referring to FIG. 4, the first distance (D1 of FIG. 3) of the second image IDT2 and the second distance D2 of the first image IDT1 may have an inverse relationship. In this case, the second distance D2 may be 0.04. The second distance D2 does not represent a physical distance between two points on the first image IDT1 as shown in FIG. 4. The second distance D2 may be a dimensionless value corresponding to the 25 Hz difference between the first center point C7 and one of the plurality of second center points C1 to C4 (e.g., C3) in the frequency domain of the second image IDT2.

Referring to FIG. 5, the second image (IDT2 of FIG. 3) may be an image on a third region R3 which is defined by the first center point C7 and a plurality of second center points C1 to C4 spaced apart from the first center point C7 by the first distance (D1 of FIG. 3), and second regions R2 corresponding to each of the plurality of second mirrors (not shown).

The plurality of second center points C1 to C4 may correspond to the centers of each of the plurality of second mirrors (not shown). The plurality of second center points C1 to C4 may define second regions R2 corresponding to each of the plurality of second mirrors (not shown) of the pupil facet mirror 222. For example, the plurality of second points C1 to C4 may be associated with the plurality of second mirrors of the pupil facet mirror 222. Each of the second regions R2 may have a shape such as a rectangle, a pentagon, and a hexagon corresponding to the plurality of second mirrors (not shown) of the actual pupil facet mirror (222 of FIG. 1). Each of the plurality of second center points C1 to C4 may refer to a center point of each of the second regions R2. The intervals between the second regions R2 (i.e., the intervals between the plurality of second center points C1 to C4) may be constant.

The first center point C7 may correspond to the center of the third region R3. The first center point C7 may be located at the center of the third region R3. The first center point C7 may refer to the center point of the third region R3.

The first distance (D1 of FIG. 3) between the first center point C7 and any one of the plurality of second center points C1 to C4 may be equal to a radius of the third region R3.

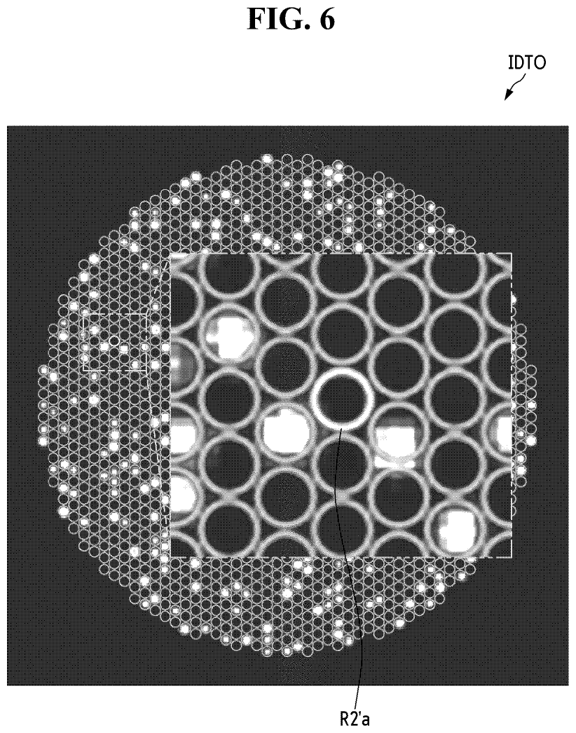

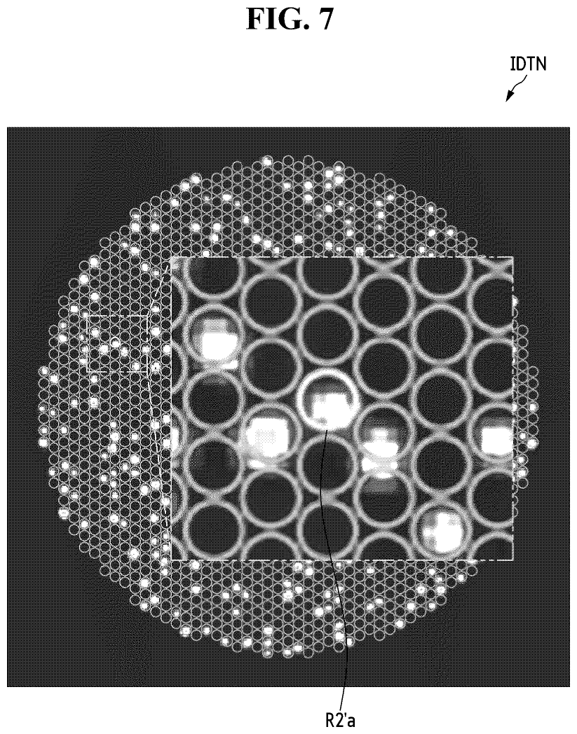

FIGS. 6 and 7 are diagrams for explaining tracking of the intensity of extreme ultra-violet mapped to each mirror of the pupil facet mirror.

Referring to FIGS. 6 and 7, the extreme ultra-violet (EL of FIG. 1) transmitted from about hundreds of field facet mirrors (221 of FIG. 1) may be mapped to individual mirror regions R2a′ of about hundreds to thousands of pupil facet mirrors (222 of FIG. 1).

Referring to FIG. 6, a third image IDTO represents the intensity of extreme ultra-violet mapped to the mirror region R2′a of any one of the pupil facet mirrors (222 of FIG. 1) measured at a first time point.

Referring to FIG. 7, a fourth image IDTN represents the intensity of extreme ultra-violet mapped to any one of the mirror regions R2′a of the pupil facet mirror (222 of FIG. 1) measured at a second time point. The second time point refers to a time point at which a predetermined time elapses after the first time point.

Comparing the third image IDTO with the fourth image IDTN, there may be a change in the intensity of extreme ultra-violet mapped to the pupil facet mirror (222 of FIG. 1) at the first and second time points. For example, such a change may occur, because the energy that should be mapped to the pupil facet mirror (222 of FIG. 1) is not correctly mapped to each mirror region of the pupil facet mirror (222 of FIG. 1) as the field facet mirror (221 of FIG. 1) is driven. In an embodiment, the alignment of the EUV light can be monitored in real time by comparing the third image IDTO with the fourth image IDTN. For example, if the intensity change of the extreme ultraviolet light mapped to the pupil facet mirror 222 exceeds a predetermined threshold, the extreme ultraviolet exposure device 1000A may be inspected to identify and correct the cause of the EUV light misalignment. The predetermined threshold may be empirically set.

However, in some embodiments, the intensity and mapping position of extreme ultra-violet mapped to each mirror region of the pupil facet mirror (222 of FIG. 1) over time may be tracked more accurately.

The processor (400 of FIG. 1) may track the intensity of the mapped extreme ultra-violet (EL of FIG. 1) over time by utilizing various indices. For example, the processor (400 of FIG. 1) may track the degree of shift of each mirror region of the pupil facet mirror (222 of FIG. 1) from the extreme ultra-violet (EL of FIG. 1) intensity, the concentrated form of the extreme ultra-violet (EL of FIG. 1) intensity in each mirror region, the amount of change in the extreme ultra-violet (EL of FIG. 1) intensity in each mirror region, and the like, by utilizing various indices, but the embodiment is not limited thereto.

In an embodiment, the processor (400 of FIG. 1) may track the amount of change in the extreme ultra-violet (EL of FIG. 1) intensity and the mapping position described above. The present disclosure may be applied to various illumination systems having a large number of mirrors in addition to those shown in FIGS. 6 and 7.

A method for extracting the optimized coordinates of the pupil region mapped to the extreme ultra-violet (EL of FIG. 1) will be explained below in detail.

FIG. 8 is a diagram for explaining the determination of the pupil region in which the intensity of the extreme ultra-violet is maximized.

Referring to FIG. 8, a first pupil region PR1 may refer to a pupil region that is preset in the monitoring device (1000 of FIG. 1). A second pupil region PR2 may correspond to the above-mentioned third region (R3 of FIG. 5). A third pupil region PR3 may refer to a pupil region optimized according to some embodiments.

The processor (400 of FIG. 1) may obtain the coordinates (x′, y′) of the center point CC2 of the third pupil region PR3 on the basis of the coordinates (x, y) of the center point CC1 of the second pupil region PR2. The coordinates (x′, y′) of the center point CC2 of the third pupil region PR3 may refer to the coordinates at which the intensity of the extreme ultra-violet (EL of FIG. 1) mapped to each of the plurality of second mirrors of the pupil facet mirror (222 of FIG. 1) is maximized. Due to the manufacturing errors of the plurality of second mirrors of the pupil facet mirror 222, the second mirrors may not be placed at the intended position within the pupil facet mirror 222. Various environment errors such as temperature and vibration in the fabrication facility may affect the intensity distribution of the EUV light. To resolve such errors, various two coordinate transformation optimization algorithms based on the optimized coordinates of the pupil region may be used.

For example, the processor (400 of FIG. 1) may obtain the coordinates (x′, y′) of the center point CC2 of the third pupil region PR3, using a Gaussian quadrature algorithm. The Gaussian quadrature algorithm may refer to a way of simplifying the pupil region into a rectangle and integrating it.

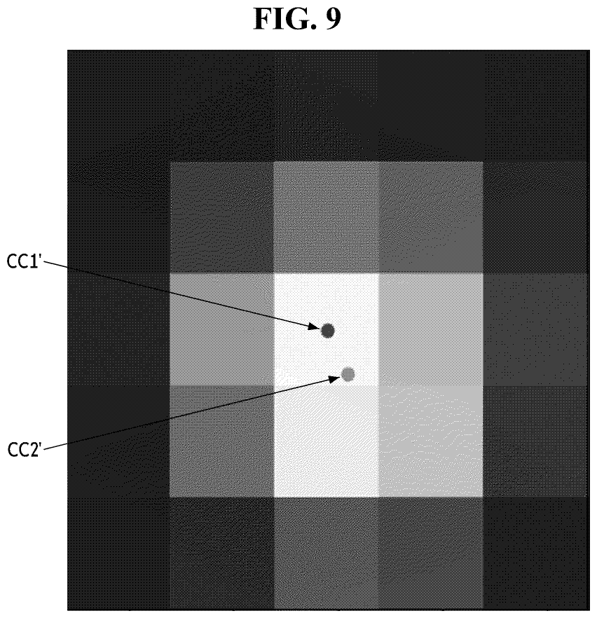

FIG. 9 is a diagram for explaining an example which obtains an optimized pupil region, using a linear interpolation algorithm.

Referring to FIG. 9, the processor (400 of FIG. 1) may obtain coordinates (x′, y′) of the center point CC2′ of the third pupil region PR3, on the basis of the coordinates (x, y) of the center point CC1′ of the second pupil region PR2, by the use of the linear interpolation algorithm.

For example, the processor (400 of FIG. 1) may set nine regions in the second pupil region PR2, and obtain data on the intensity of extreme ultra-violet (EL of FIG. 1) in each of the nine regions. The processor (400 of FIG. 1) may obtain the coordinates (x′, y′) of the center point CC2′ of the third pupil region PR3 at which the sum of the data is maximized, on the basis of the coordinates (x, y) of the center point CC1′ of the second pupil region PR2.

In such a case, the processor (400 of FIG. 1) may acquire the coordinates of the center point CC2′ of the third pupil region PR3, in the way of obtaining a value (i.e., a maximum integral value) at which the sum of the data of the nine regions is maximized, on the basis of the center point CC1′ of the second pupil region PR2. FIG. 9 shows nine regions set around the coordinates (x, y) of the center point CC1′ of the second pupil region PR2. The processor 400 may incrementally shift these nine regions horizontally and/or vertically, summing data at each position. By identifying the position with the maximum integral value, the processor 400 determines the coordinate of the center point CC2′ of the third pupil region PR3.

The processor (400 of FIG. 1) may obtain the coordinates (x′, y′) of the center point (CC2 of FIG. 8) of the third pupil region PR3, using a 2D plane transformation matrix.

That is, the processor (400 of FIG. 1) may transform the coordinates (x, y) of the center point (CC1 of FIG. 8) of the second pupil region PR2 into the coordinates (x′, y′) of the center point (CC2 of FIG. 8) of the third pupil region PR3, using the following Formula 1.

$$[ \begin{matrix}{x}^{′} \\ {y}^{′}\end{matrix} ] = A \cdot B \cdot [ \begin{matrix}x \\ y\end{matrix} ] + C \qquad ( Formula 1 )$$

$$A = [ \begin{matrix}cos θ & - sin θ \\ sin θ & cos θ\end{matrix} ] \qquad ( Formula 2 )$$

$$B = [ \begin{matrix}SCx & SHy \\ SHx & SCy\end{matrix} ] \qquad ( Formula 3 )$$

$$C = [ \begin{matrix}Tx \\ Ty\end{matrix} ] \qquad ( Formula 4 )$$

Here, A refers to a rotation transformation matrix defined by Formula (2), and θ refers to a rotation angle. B refers to a scale and shear transformation matrix defined by Formula (3), and SC refers to a scale shear factor, and SH refers to a shear transformation factor. C refers to a migration matrix defined by Formula (4), and T refers to a migration transformation factor.

In this case, the aforementioned transformation factors may be adjusted to obtain the coordinates (x′, y′) of the center point (CC2 of FIG. 8) of the third pupil region PR3.

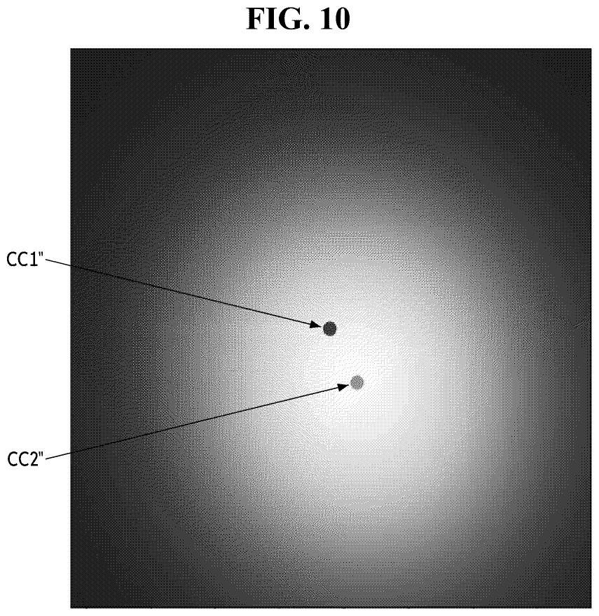

FIG. 10 is a diagram for explaining obtaining an optimized pupil region by the use of a Gaussian function.

Referring to FIG. 10, the processor (400 of FIG. 1) may obtain the coordinates (x′, y′) of the center point CC2″ of the third pupil region PR3, on the basis of the coordinates (x, y) of the center point CC1″ of the second pupil region PR2, by the use of Gaussian function fitting instead of the Gaussian quadrature algorithm.

In this case, the value at which the sum of the data on the intensity of the extreme ultra-violet (EL of FIG. 1) is maximized may be acquired through the Gaussian function fitting.

The intensity data of the extreme ultra-violet (EL of FIG. 1) may be assumed to be a value having a normal distribution. Under such an assumption, the coordinates (x′, y′) of the center point CC2″ of the third pupil region PR3 may be obtained on the basis of the data having the maximum value in the normal distribution curve.

Alternatively, the processor (400 of FIG. 1) may obtain the coordinates (x′, y′) of the center point CC2″ of the third pupil region PR3, by the use of a 2D spline curve instead of the Gaussian function fitting.

The processor (400 of FIG. 1) may obtain the coordinates (x′, y′) of the center point (CC2 of FIG. 8) of the third pupil region PR3, by the use of a linear regression algorithm instead of a 2D plane transformation matrix.

That is, the processor (400 of FIG. 1) may acquire the coordinates (x′, y′) of the center point (CC2 of FIG. 8) of the third pupil region PR3, on the basis of the coordinates (x, y) of the center point (CC1 of FIG. 8) of the second pupil region PR2, by the use of the following Formula (5).

$$f ( x ) = {k}_{1} + {k}_{3} x + {k}_{5} y + {k}_{7} {x}^{2} + {k}_{9} xy + {k}_{11} {y}^{2} \qquad ( Formula 5 )$$

$$f ( y ) = {k}_{2} + {k}_{4} y + {k}_{6} x + {k}_{8} {y}^{2} + {k}_{10} yx + {k}_{12} {x}^{2}$$

Here, f(x) and f(y) may refer to the coordinates (x′, y′) of the center point (CC2 of FIG. 8) of the third pupil region PR3 respectively. k₁ to k₁₂ may refer to constants that are arbitrarily set. The coordinates of the optimized pupil region may be obtained by adjusting the values of k₁ to k₁₂.

The processor (400 of FIG. 1) may visualize a difference between the coordinates (x, y) of the center point (CC1 of FIG. 8) of the second pupil region (PR2 of FIG. 8) and the coordinates (x′, y′) of the center point (CC2 of FIG. 8) of the third pupil region (PR3 of FIG. 8) acquired as described above. For example, a tendency of the coordinates of the pupil region may be grasped, by the use of a vector in which the coordinates (x, y) of the center point (CC1 of FIG. 8) of the second pupil region (PR2 of FIG. 8) is set as a start point, and the coordinates (x′, y′) of the center point (CC2 of FIG. 8) of the third pupil region (PR3 of FIG. 8) is set as an end point.

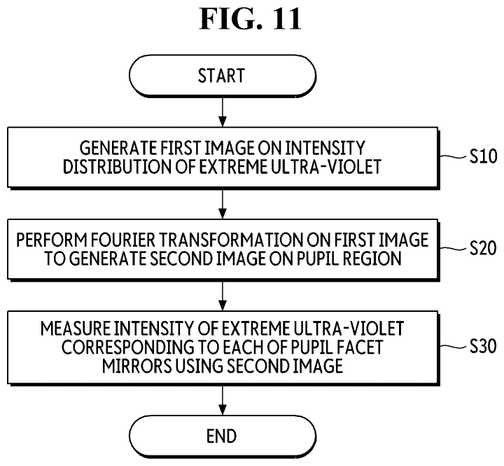

FIG. 11 is a flowchart for explaining a monitoring method using the monitoring device according to some embodiments.

Referring to FIG. 11, first, the sensor module (300 of FIG. 1) may generate a first image (IDT1 of FIG. 2) on the intensity distribution of extreme ultra-violet (EL of FIG. 1) reflected from a plurality of mirrors (S10).

Thereafter, the processor (400 of FIG. 1) may perform a Fourier transform on the first image (IDT1 of FIG. 2) to generate a second image (IDT2 of FIG. 3) on the first pupil region (R3 of FIG. 5) which has the first center point (C7 of FIG. 3) and the plurality of first patterns (C1 to C4 of FIG. 3) spaced apart from the first center point (C7 of FIG. 3) by the first distance (D1 of FIG. 3) (S20). For example, the second image IDT2 of FIG. 3 may represent the first pupil region R3 of FIG. 3.

After that, the processor (400 of FIG. 1) may measure the intensity of the extreme ultra-violet (EL of FIG. 1) mapped to each of the plurality of mirrors, using the first center point (C7 of FIG. 3) (S30).

The processor (400 of FIG. 1) may determine the coordinates of the second center point (CC2 of FIG. 8) of the second pupil region (PR3 of FIG. 8) in which the intensity of the extreme ultra-violet (EL of FIG. 1) mapped to each of the plurality of mirrors is maximized, on the basis of the coordinates of the first center point (C7 of FIG. 3).

Although the embodiments of the present invention have been described above with reference to the accompanying drawings, the present invention is not limited to the above embodiments, and may be fabricated in various different forms. Those skilled in the art will appreciate that the present invention may be embodied in other specific forms without changing the technical spirit or essential features of the present invention. Accordingly, the above-described embodiments should be understood in all respects as illustrative and not restrictive.

What is claimed is:

1. An extreme ultra-violet (EUV) lithography system comprising:
a source module which generates light;
a field facet mirror which includes a plurality of first mirrors that collect the light transmitted from the source module;
a pupil facet mirror which includes a plurality of second mirrors that transmit the light transmitted from the field facet mirror to a reticle;
a projection optical system which transmits the light reflected from the reticle to a substrate;
a sensor module which is disposed on a substrate stage that supports the substrate, and which generates a first image representing a light intensity distribution; and
a processor configured to perform a Fourier transformation on the first image to generate a second image representing a first pupil region defined by a first center point and a plurality of second center points each spaced apart from the first center point by a first distance,
wherein the first center point is located at a center of the first pupil region.

2. The EUV lithography system of claim 1,
wherein the plurality of second center points are associated with each of the plurality of second mirrors.

3. The EUV lithography system of claim 1,
wherein a distance between the first center point and any one of the plurality of second center points is equal to a radius of the first pupil region.

4. The EUV lithography system of claim 1,
wherein the processor is configured further to: obtain a second coordinate at which an intensity of the light mapped to each of the plurality of second mirrors is maximized, on the basis of a first coordinate of the first center point.

5. The EUV lithography system of claim 4,
wherein the processor is configured further to obtain the second coordinate, using a Gaussian quadrature algorithm.

6. The EUV lithography system of claim 4,
wherein the processor is configured further to obtain the second coordinate, using a linear interpolation algorithm.

7. The EUV lithography system of claim 4,
wherein the processor is configured further to obtain the second coordinate, using a Gaussian function fitting algorithm.

8. The EUV lithography system of claim 4,
wherein the processor is configured further to obtain the second coordinate, using a coordinate transformation matrix.

9. The EUV lithography system of claim 4,
wherein the processor is configured further to obtain the second coordinate, using a linear regression algorithm.

10. An extreme ultra-violet (EUV) lithography system comprising:
a source module which generates an extreme ultra-violet light;
a first optical system which includes a field facet mirror that collects the extreme ultra-violet light and a pupil facet mirror that transmits the extreme ultra-violet light transmitted from the field facet mirror to a reticle, the field facet mirror including a plurality of first mirrors, and the pupil facet mirror including a plurality of second mirrors;
a second optical system which transmits the extreme ultra-violet light reflected from the reticle to a substrate;
a sensor module which is disposed on a substrate stage that supports the substrate, and which generates a first image representing an intensity distribution of the extreme ultra-violet light; and
a processor configured to:
perform a Fourier transform on the first image to generate a second image representing a first pupil region having a first center point and a plurality of second center points; and
measure an intensity of the extreme ultra-violet light mapped to each of the plurality of second mirrors from the first center point,
wherein the plurality of second center points are associated with the plurality of second mirrors.

11. The EUV lithography system of claim 10,
wherein each of the plurality of second center points is spaced apart from the first center point by a first distance.

12. The EUV lithography system of claim 11,
wherein the first distance is equal to a radius of the first pupil region.

13. The EUV lithography system of claim 11,
wherein each of the regions associated with the plurality of second mirrors has a shape corresponding to each of the plurality of second mirrors.

14. The EUV lithography system of claim 10,
wherein the processor is configured further to obtain a coordinate of a third center point of a second pupil region at which the intensity of the extreme ultra-violet light mapped to each of the plurality of second mirrors is maximized, on the basis of a coordinate of the first center point.

15. The EUV lithography system of claim 14,
wherein the processor is configured further to:
set nine regions inside the first pupil region, using a linear interpolation algorithm;
acquire data on the intensity of the extreme ultra-violet light in each of the nine regions; and
perform a Gaussian quadrature algorithm to obtain the coordinate of the third center point at which a sum of the data is maximized, on the basis of the coordinate of the first center point.

16. The EUV lithography system of claim 14,
wherein the processor is configured further to obtain the coordinate of the third center point, using a Gaussian function fitting algorithm.

17. The EUV lithography system of claim 14,
wherein the processor is configured further to obtain the coordinate of the third center point, using a coordinate transformation matrix.

18. The EUV lithography system of claim 14,
wherein the processor is configured further to obtain the coordinate of the third center point, using a linear regression algorithm.

19. An extreme ultra-violet (EUV) lithography system comprising:
a source module which generates an extreme ultra-violet light;
an optical module which transfers a pattern onto a substrate, using the extreme ultra-violet light,
the optical module including:
a collector which collects and reflects the extreme ultra-violet light generated from the source module,
an illumination optical system which includes a field facet mirror including a plurality of first mirrors that reflects the extreme ultra-violet light emitted from the collector, and a pupil facet mirror including a plurality of second mirrors that transmit the extreme ultra-violet light transmitted from the field facet mirror to a reticle, and
a projection optical system which transmits the extreme ultra-violet light reflected from the reticle to the substrate;
a sensor module which is disposed on a substrate stage that supports the substrate, and which generates a first image on an intensity distribution of the extreme ultra-violet light; and
a processor configured to perform a Fourier transformation on the first image to generate a second image representing a first pupil region defined by a first center point and a plurality of second center points,
wherein the plurality of second center points are associated with centers of the plurality of second mirrors,
wherein the first center point corresponds to a center of the first pupil region, and
wherein the processor is configured further to measure an intensity of the extreme ultra-violet light mapped to the plurality of second mirrors, using the first center point.

20. The EUV lithography system of claim 19,
wherein the processor is configured further to obtain a third center point of a second pupil region in which the intensity of the extreme ultra-violet light mapped to each of the plurality of second mirrors is maximized, using the first center point.
